(19) United States
(12) Patent Application Publication
(10) Pub. No.: US 2002/0182753 A1
(43) Pub. Date: Dec. 5, 2002

(54) Method of forming a capacitor in a FeRAM

(76) Inventor: Jih-Shiang Jenq, Ping-Tung City (TW)

Correspondence Address: NAIPO (NORTH AMERICA INTERNATIONAL PATENT OFFICE), P.O. BOX 506, MERRIFIELD, VA, 22116, US

(21) Appl. No.: 09/865,564

(22) Filed: May 29, 2001

(51) Int. Cl. H01L 21/00; H01L 21/8242

(52) U.S. Cl. 438/3; 438/239

(57) ABSTRACT

An insulation layer is formed on the substrate of a semiconductor wafer. A bottom electrode is formed on the surface of the insulation layer followed by forming a dielectric layer to cover the bottom electrode. Thereafter, an etching process forms an upper electrode hole within the dielectric layer to connect to the surface of the bottom electrode. A spacer is formed around the walls within the upper electrode hole. A capacitor dielectric layer is then formed on the surface of the dielectric layer, on the bottom within the upper electrode hole, and on the spacer. Finally, an upper electrode is formed within the upper electrode hole to complete fabrication of a capacitor.

### BACKGROUND OF THE INVENTION

1. Field of the Invention

The present invention relates to a method of forming a capacitor in a random access memory (RAM) device, and more particularly, to a method of forming a capacitor in a ferroelectric random access memory (FeRAM) device.

2. Description of the Prior Art

A semiconductor memory is a very important element in a computer system. It can store simple data by a single memory cell, or it can combine numerous memory cells to perform logic computation. Each memory cell is composed of a metal oxide semiconductor (MOS) transistor and a capacitor. The MOS transistor is electrically connected to a word line while the capacitor is electrically connected to a bit line, and together, they decide the address of a memory cell.

The capacitor of a memory cell is made up of two electrical layers on a semiconductor wafer. One electrical layer is used as an upper electrode while the other is used as a bottom electrode. A cell dielectric layer is positioned between the two electrical layers as an insulator. For a random access memory cell to function in such a structure, one of the electrical layers obtains induced negative charges while the other supplies an electric field to have positive charges, enabling the capacitor to memorize or output data. Conversely, one of the electrical layers may lose the induced charges while the other does not supply the electric field, returning the charges' distribution on the two electrical layers back to original states.

Since data stored in the random access memory may disappear on cutting the power supply, some important information, such as a computer starting testing program, must be stored in a non-volatile memory. However, the accessing speed of a non-volatile memory is slower than that of a volatile memory. In order to improve the memory performance, ferroelectric materials have been recently used to replace the conventional cell dielectric layer in the random access memory. Due to a hysteresis characteristic of ferroelectric materials, data stored in the random access memory does not disappear when the power supply is cut, and at the same time, a faster accessing speed is achieved.

Please refer to FIG. 1 to FIG. 4 of schematic diagrams of forming a capacitor in a FeRAM according to the prior art. As shown in FIG. 1, a semiconductor wafer 10 is provided. A low pressure chemical vapor deposition (LPCVD) method is used to form a silicon oxide layer 14 on a surface of the substrate 12 of the semiconductor wafer 10. The silicon oxide layer 14 is approximately 6000 to 8000 Angstroms (Å) thick and functions as an insulation layer to insulate the capacitor from a MOS transistor. Following this, a conductive layer 18 and a photoresist layer 20 are formed, respectively, on a surface of the semiconductor wafer 10. The conductive layer 18 is approximately 8000 to 10000 Å thick, providing sufficient area for storing charges. A photolithographic process is then performed to define patterns of a bottom electrode within the photoresist layer 20. The conductive layer 18 may electrically connect to a node contact (not shown), using the node contact as an electrical connector between the capacitor and the MOS transistor. Alternatively, other connecting structures can also be used to electrically connect the capacitor to the MOS transistor.

As shown in FIG. 2, an anisotropic dry etching process is performed to remove a portion of the conductive layer 18 following the patterns within the photoresist layer 20 down to the surface of the insulation layer 14, forming a bottom electrode 21. After the photoresist layer 20 is removed, a ferroelectric layer 22 and another photoresist layer 24 are formed respectively on the surface of the semiconductor wafer 10. A photolithographic process is thereafter performed to form patterns of a capacitor dielectric layer within the photoresist layer 24.

As shown in FIG. 3, using the patterned photoresist layer 24 as a mask, an etching process is performed to remove a portion of the ferroelectric layer 22 down to a surface of the bottom electrode 21 and a surface of the insulation layer 14. As a result, a capacitor dielectric layer 23 is formed atop the bottom electrode 21. During the etching process to remove the ferroelectric layer 22, an etching time is often increased to over etch the ferroelectric layer 22 to ensure the ferroelectric layer 22 is completely removed from the semiconductor wafer 10 except for on the surface of the bottom electrode 21. With the over-etching of the ferroelectric layer 22, the profile of the capacitor dielectric layer 23 is precisely controlled to satisfy the requirement of uniformity in a semiconductor process.

The over-etching of the ferroelectric layer 22, however, also brings an etched damage region a within the capacitor dielectric layer 23. For example, if errors from the photolithographic process are neglected, a width c of the capacitor dielectric layer 23 should have a maximum value equaling a width b of the bottom electrode 21. Since the capacitor dielectric layer 23 is damaged by over-etching or insufficient selectivity of the etching solution, the width c of the capacitor dielectric layer 23 may possibly be smaller than the width b of the bottom electrode 21. The contact surface between the capacitor dielectric layer 23 and the bottom electrode 21 is thus decreased to lower the storage ability of the capacitor. In addition, resulting from the over-etching of the capacitor dielectric layer 23, the surface of the bottom electrode 21 is exposed in an etched damage region a. The exposed surface of the bottom electrode 21 suffers ions impact or etching in the etching process, thus destroying the structure within the bottom electrode 21 to induce leakage currents.

As shown in FIG. 4, after the capacitor dielectric layer 23 is formed, the deposition, photolithographic and etching processes are repeated to form an upper electrode 26 atop the capacitor dielectric layer 23. Following that, the fabrication process of the prior FeRAM capacitor is completed. Inevitably, during the etching process for defining a profile of the upper electrode 26, an etched damage region can also be formed. The contact surface between the upper electrode 26 and the capacitor dielectric layer 23 is decreased, and the bottom electrode 21 suffers destruction again affecting the performance of the memory.

### SUMMARY OF THE INVENTION

It is therefore an objective of the present invention to provide a method of forming a capacitor in a FeRAM to prevent etching damages on the structure of the FeRAM.

It is another objective of the present invention to provide a method of enhancing qualities of a capacitor dielectric layer in a FeRAM capacitor.

According to the claimed invention, an insulation layer is formed on the substrate of a semiconductor wafer. A bottom electrode is formed on a surface of an insulation layer followed by forming a dielectric layer to cover the bottom electrode. Thereafter, an etching process is performed to form an upper electrode hole within the dielectric layer to connect to a surface of the bottom electrode. A spacer is formed around the walls within the upper electrode hole. A capacitor dielectric layer is then formed on a surface of the dielectric layer, on the bottom within the upper electrode hole, and on the spacer. Finally, an upper electrode is formed within the upper electrode hole to complete fabrication of the capacitor.

It is an advantage of the present invention that the capacitor dielectric layer and the upper electrode are formed above the bottom electrode by a self-alignment contact (SAC) technique. Hence, an etching process for defining the profile of the capacitor dielectric layer is omitted. The etched damages and process errors are prevented to improve the performance of the memory. In addition, omitting the etching process also prevents an exposure of the surface of the bottom electrode, thus preventing leakage currents and structural damage on the bottom electrode.

These and other objectives of the present invention will no doubt become obvious to those of ordinary skill in the art after reading the following detailed description of the preferred embodiment, that is illustrated in the various figures and drawings.

### BRIEF DESCRIPTION OF THE DRAWINGS

FIG. 1 to FIG. 4 are schematic diagrams of forming a capacitor in a FeRAM according to the prior art.

FIG. 5 to FIG. 10 are schematic diagrams of forming a capacitor in a FeRAM according to the present invention.

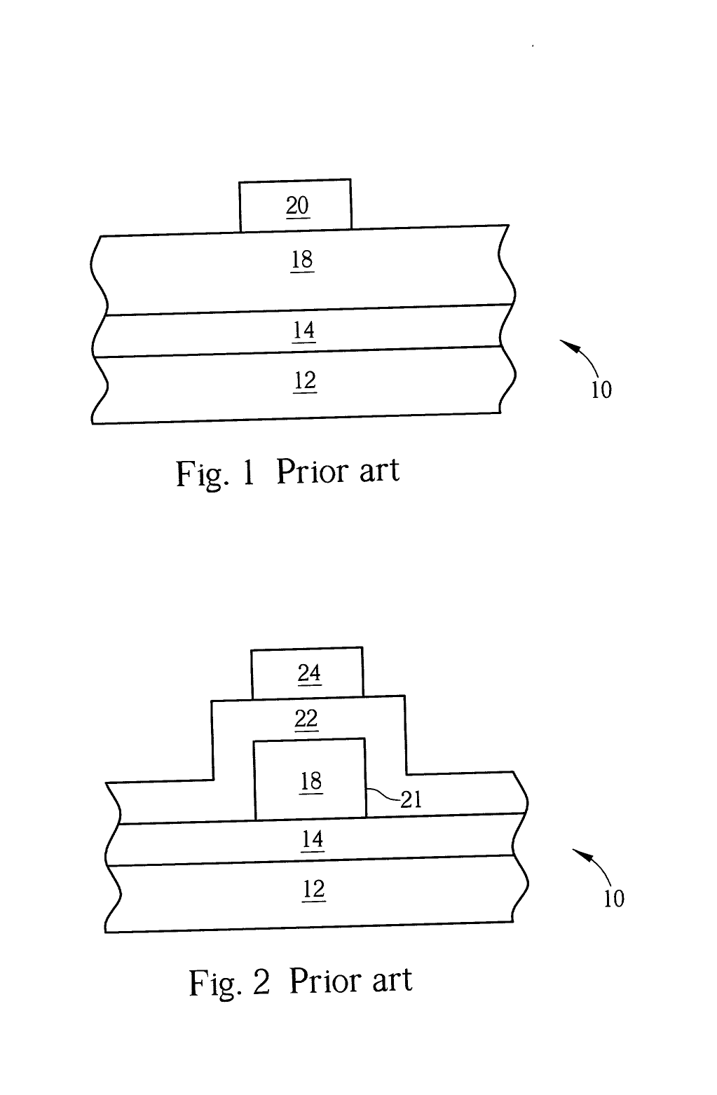

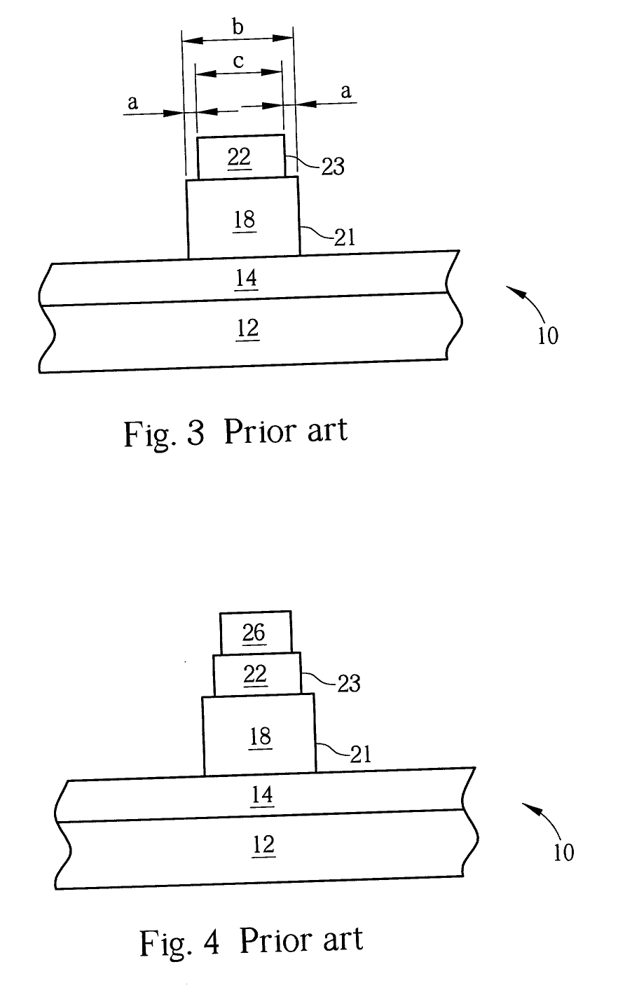

### DETAILED DESCRIPTION OF THE PREFERRED EMBODIMENT

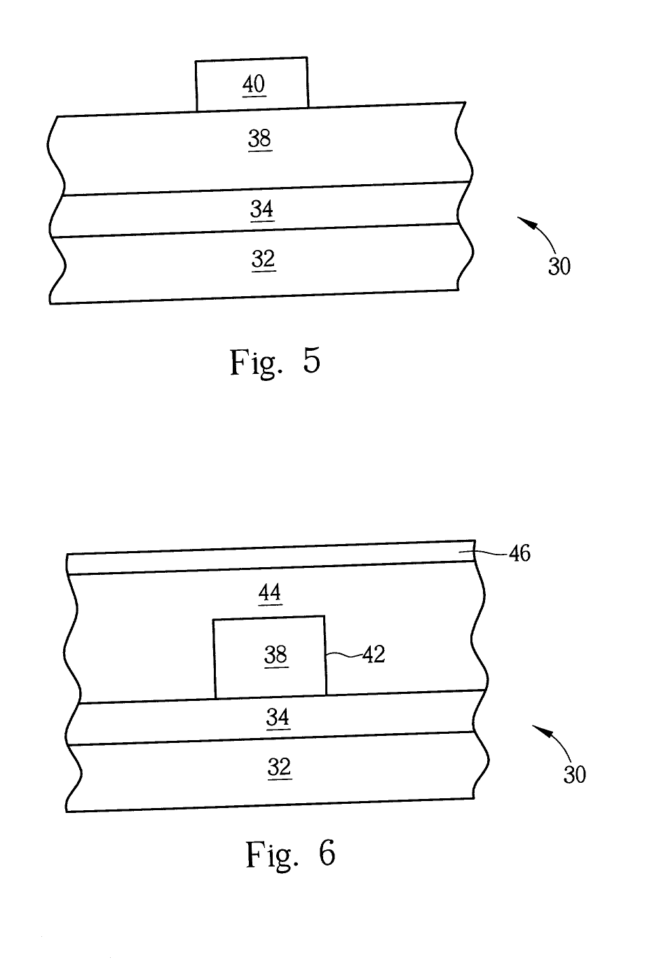

Please refer to FIG. 5 to FIG. 10 of schematic diagrams of a method of forming a capacitor in a FeRAM on a semiconductor wafer 30 according to the present invention. As shown in FIG. 5, the semiconductor wafer 30 comprises a substrate 32, and an insulation layer 34 of approximately 6000 to 8000 Å thick positioned on the surface of the substrate 32. According to a best embodiment of the present invention, the insulation layer 34 is a silicon oxide layer forming by LPCVD. A conductive layer 38, such as a noble metal layer consisting of platinum (Pt), palladium (Pd), iridium (Ir), rhodium (Rh), osmium (Os), or ruthenium (Ru), is formed on a surface of the semiconductor wafer 30. The conductive layer 38 is approximately 8000 to 10000 Å thick, providing sufficient surface area for storing charges. The conductive layer 38 may electrically connect to a node contact (not shown), using the node contact as an electrical connector between the capacitor and a MOS transistor. Alternatively, other connecting structures can also be used to electrically connect the capacitor to the MOS transistor. In other embodiments of the present invention, the conductive layer 38 can be a composite layer, composing both a platinum layer and a titanium layer, or composing a platinum layer, an iridium dioxide (IrO₂) layer and an iridium layer. Following this, a photoresist layer 40 is formed on a surface of the conductive layer 38. A photolithographic process is then performed to define patterns of a bottom electrode within the photoresist layer 40.

As shown in FIG. 5, following the formation of patterns within the photoresist layer 40, an anisotropic dry etching process is performed to remove a portion of the conductive layer 38 down to the surface of the insulation layer 34, forming a bottom electrode 42. After the photoresist layer 40 is removed, an insulation layer 44 of silicon dioxide (SiO₂) and an insulation layer 46 of titanium dioxide (TiO₂) are formed, respectively, on the surface of the semiconductor wafer 30. Therein, the SiO₂ insulation layer 44 is deposited with a deposition depth greater than the height of the bottom electrode 42, to planarize the surface of the semiconductor wafer 30 and reduce the height difference on the surface of the semiconductor wafer 30. The TiO₂ insulation layer 46 functions as a barrier layer to insulate the SiO₂ insulation layer 44 from the materials forming on the semiconductor wafer 30 in a later process.

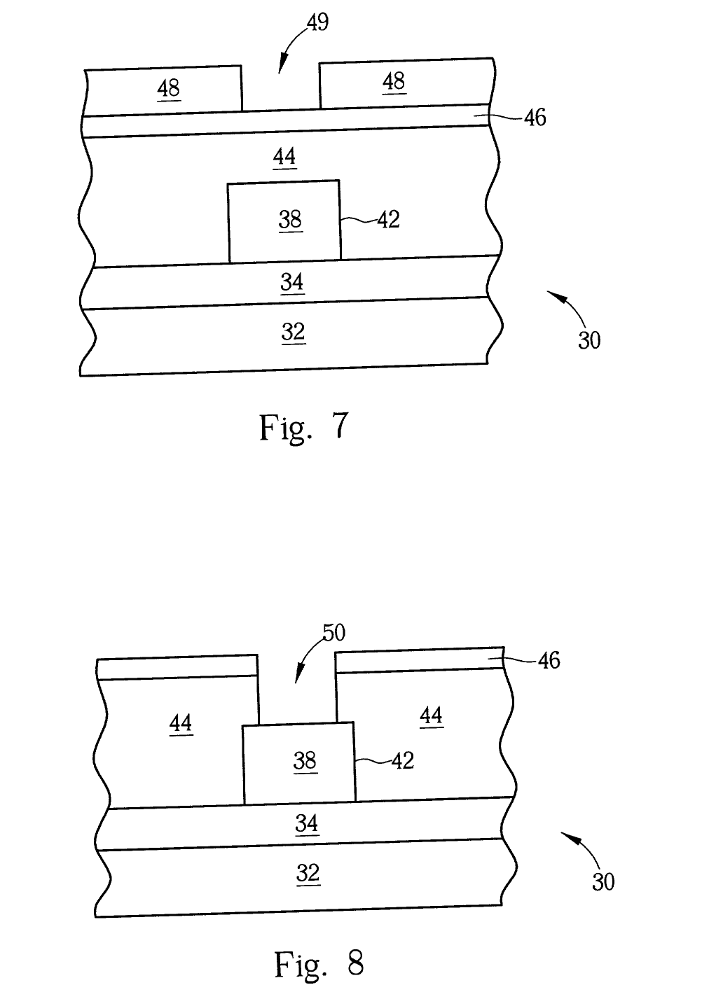

Then, as shown in FIG. 7, a photoresist layer 48 is formed on the surface of the TiO₂ insulation layer 46. A photolithographic process is thereafter performed to form an opening 49 within the photoresist layer 48 to define patterns and positions for forming an upper electrode hole. As shown in FIG. 8, an anisotropic etching process is performed following patterns within the photoresist layer 48 to etch the insulation layers 46 and 44, thus deepening the opening 49 down to the surface of the bottom electrode 48 to form an upper electrode hole 50.

As shown in FIG. 9, after the upper electrode hole 50 is formed, a portion of the SiO₂ insulation layer 44 within the upper electrode hole 50 is exposed. Another insulation layer (not shown), such as a titanium dioxide layer, is thus required to be deposited on the semiconductor wafer 30 followed by etching back a portion of the insulation layer to form a spacer 52 around the wall within the upper electrode hole 50. The spacer 52 is made of a conductive or dielectric material, which does not react with the SiO₂ insulation layer 44. By combining the spacer 52 and the TiO₂ insulation layer 46, the SiO₂ insulation layer 44 is thus completely insulated from materials formed on the semiconductor wafer 30 in a later process.

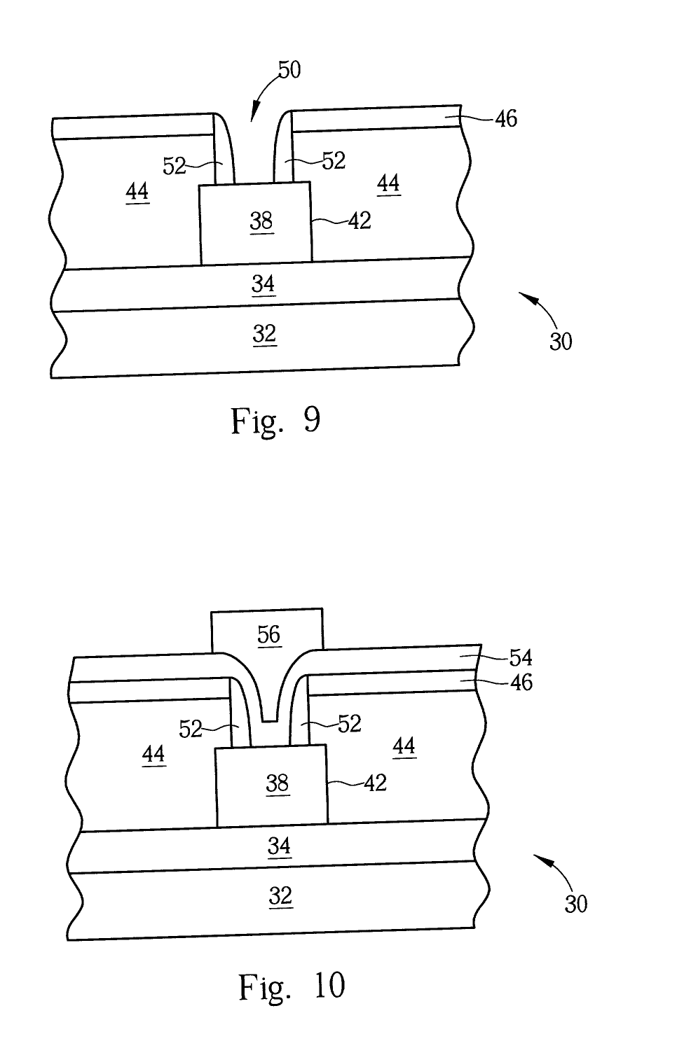

As shown in FIG. 10, a ferroelectric layer, such as a lead zirconate titanate (PZT) layer, is formed to cover the semiconductor wafer 30 and the upper electrode hole 50 forming a capacitor dielectric layer 54. Following that, an upper electrode 56 of iridium dioxide is formed on the surface of the capacitor dielectric layer 54, thus finishing fabrication of the FeRAM capacitor of the present invention. Alternatively, the upper electrode 56 can be formed of platinum (Pt), copper (Cu), aluminum (Al), titanium (Ti), or titanium nitride (TiN).

In order to prevent occurrence of an etched damage region within the capacitor dielectric layer 54, and prevent structural damage on the bottom electrode 42, a self-alignment contact (SAC) technique is used to form the capacitor dielectric layer 54 according to the present invention. Using the SAC technique, the thick insulation layer 44 is first deposited on the bottom electrode 42. Then, the upper electrode hole 50 is formed to penetrate the insulation layer 44 to a surface of the bottom electrode 42. Following that, materials for forming the capacitor dielectric layer 54 and the upper electrode 56 are filled, respectively, within the upper electrode hole 50 to form the self-aligned capacitor dielectric layer 54 and upper electrode 56. As a result, the etching process for defining the profile of the capacitor dielectric layer in the prior art is omitted. The unwanted etched damages and process errors are prevented, improving the performance of the memory. In addition, omitting the etching process also prevents structural damage on the bottom electrode, thus preventing leakage currents.

In contrast to the prior art of forming a capacitor in a FeRAM, the method of the present invention uses a SAC technique to form the capacitor dielectric layer and the upper electrode above the bottom electrode. Hence, the etching process for defining the profile of the capacitor dielectric layer in the prior art is omitted. The etched damages and process errors are prevented, and the qualities of the capacitor dielectric layer and the performance of the memory are improved. In addition, increasing the depth of the upper electrode hole, results in the capacitor having an increased effective surface area for storing charges. As a result, the planar width of the capacitor shrinks to raise integration of the semiconductor elements. Furthermore, the present invention forms the TiO₂ spacer and the TiO₂ insulation layer to insulate the SiO₂ insulation layer from the capacitor dielectric layer. Since the SiO₂ insulation layer is effectively insulated from the capacitor dielectric layer, reactions between these two layers are prevented and structural damage on the capacitor dielectric layer is also prevented.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of forming a capacitor in a ferroelectric random access memory (FeRAM) on a semiconductor wafer, the semiconductor wafer comprising a substrate, and an insulation layer positioned on the substrate, the method comprising:
forming a bottom electrode on the insulation layer;
forming a dielectric layer on the semiconductor wafer covering the bottom electrode;
performing an etching process to form an upper electrode hole in the dielectric layer through to the surface of the bottom electrode;
forming a spacer around the walls within the upper electrode hole;
forming a capacitor dielectric layer on the surface of the dielectric layer, on the bottom within the upper electrode hole, and on the spacer; and
forming an upper electrode in the upper electrode hole.

2. The method of claim 1 wherein the bottom electrode is composed of noble metals consisting of platinum (Pt), palladium (Pd), iridium (Ir), rhodium (Rh), osmium (Os), or ruthenium (Ru).

3. The method of claim 1 wherein the bottom electrode is composed of both a platinum layer and a titanium layer, or is composed of a platinum layer, an iridium dioxide (IrO₂) layer and an iridium layer.

4. The method of claim 1 wherein the capacitor dielectric layer is composed of lead zirconate titanate (PZT).

5. The method of claim 1 wherein the dielectric layer is composed of both a silicon dioxide layer and a titanium dioxide (TiO₂) layer.

6. The method of claim 5 wherein the spacer is composed of titanium dioxide, and is used to prevent the capacitor dielectric layer formed of PZT from reacting with the silicon dioxide layer.

7. The method of claim 1 wherein the upper electrode is composed of iridium dioxide.

8. The method of claim 1 wherein the upper electrode comprises of platinum (Pt), copper (Cu), aluminum (Al), titanium (Ti), or titanium nitride (TiN).

9. A method of enhancing the qualities of a capacitor dielectric layer in a capacitor in a ferroelectric random access memory (FeRAM) on a semiconductor wafer, the semiconductor wafer comprising a substrate, and an insulation layer positioned on the substrate, the method comprising:
forming a bottom electrode on the insulation layer;
forming a silicon dioxide layer on the semiconductor wafer covering the bottom electrode;
forming a titanium dioxide (TiO₂) layer on the silicon dioxide layer;
performing an etching process to form an upper electrode hole in the titanium dioxide layer and the silicon dioxide layer through to the surface of the bottom electrode;
forming a spacer of titanium dioxide around the walls within the upper electrode hole;
forming the capacitor dielectric layer of lead zirconate titanate (PZT) on the surface of the titanium dioxide layer, on the bottom within the upper electrode hole, and on the spacer; and
forming an upper electrode in the upper electrode hole;
wherein the titanium dioxide layer and the spacer composed of titanium dioxide are both used to prevent the capacitor dielectric layer formed of PZT from reacting with the silicon dioxide layer so as to prevent the capacitor dielectric layer from cracking or lifting.

10. The method of claim 9 wherein the bottom electrode is composed of noble metals consisting of platinum (Pt), palladium (Pd), iridium (Ir), rhodium (Rh), osmium (Os), or ruthenium (Ru).

11. The method of claim 9 wherein the bottom electrode is composed of both a platinum layer and a titanium layer, or is composed of a platinum layer, an iridium dioxide (IrO₂) layer and an iridium layer.

12. The method of claim 9 wherein the upper electrode is composed of iridium dioxide.

13. The method of claim 9 wherein the upper electrode comprises of platinum (Pt), copper (Cu), aluminum (Al), titanium (Ti), or titanium nitride (TiN).
